(19) United States
(12) Patent Application Publication
(10) Pub. No.: US 2006/0079036 A1
(43) Pub. Date: Apr. 13, 2006

(54) METHOD OF MANUFACTURING GATE, THIN FILM TRANSISTOR AND PIXEL

(76) Inventors: Ta-Jung Su, Changhua County (TW); Chin-Tzu Kao, Changhua County (TW); Mi-Cheng Lai, Taoyuan County (TW); Yi-Tsai Hsu, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,835

(22) Filed: Oct. 8, 2004

(51) Int. Cl. H01L 21/4763

(52) U.S. Cl. 438/158; 438/585; 438/592

(57) ABSTRACT

A method of manufacturing a gate, a thin film transistor and a pixel. First, a patterned mask layer is formed on a substrate. The mask layer exposes an area for forming the gate. A gate is formed on the exposed area of the substrate and then the mask layer is removed. The method produces a gate having a well-defined profile. When the method is applied to form a transistor or a pixel, coverage of a subsequently form film layer is improved and point discharge is prevented.

### BACKGROUND OF THE INVENTION

1. Field of the Invention

The present invention relates to a method of manufacturing semiconductor device. More particularly, the present invention relates to a method of manufacturing gate, thin film transistor and pixel.

2. Description of Related Art

A thin film transistor liquid crystal display mainly comprises a thin film transistor array substrate, a color filtering array substrate and a liquid crystal layer. The thin film transistor array substrate includes an array of thin film transistors and pixel electrodes that correspond to each one of thin film transistors. The principles behind the operation of a thin film transistor are very similar to the operation of a conventional metallic-oxide-semiconductor (MOS) transistor. Both the thin film transistor and the MOS transistor are devices having three terminals (a gate, a drain and a source). In general, each thin film transistor functions as a switching element inside a liquid crystal pixel unit.

Typically, a thin film transistor array substrate is fabricated by performing a number of photolithographic and etching operations. In other words, an exposure process is carried out to transfer a pattern of a photomask to a photoresist layer over a substrate and then the photoresist layer is developed to form a patterned photoresist layer. Thereafter, using the patterned photoresist layer as an etching mask, the film layers on the substrate are etched to form the gate, the channel layer, the source/drain, the pixel electrode and the passivation layer of a thin film transistor in sequence.

However, with the demands for larger size display panels, the gate is often fabricated using a conductive material having a high electrical conductivity such as a metal to reduce line resistance. Yet, a metallic gate is vulnerable to oxidation. To prevent the effect of over-oxidation on the electrical performance of the display panel, an oxidation-resistant layer such as a metallic alloy or a metal nitride layer is often formed over the metallic gate to serve as a protective layer. However, because the etching rate between a metallic layer and an oxidation-resistant layer are different in a wet etching operation, the conventional method of fabricating the gate frequently leads to the under-cutting of a portion of the metallic layer.

FIGS. 1A through 1D are schematic cross-sectional views showing the steps of fabricating a conventional gate having an overlying oxidation-resistant layer. First, as shown in FIG. 1A, a substrate 100 having a metallic layer 102a and an oxidation-resistant layer 102b formed thereon is provided. Thereafter, a patterned photoresist layer 110 is formed over the oxidation-resistant layer 102b.

As shown in FIG. 1B, a wet etching operation is carried out using an etching solution to remove a portion of the metallic layer 102a and the oxidation-resistant layer 102b. Because the etching rate between the metallic layer 102a and the oxidation-resistant layer 102b with respect to the same etching solution are different, therefore the metallic layer 102a will be over-etched forming an undercut 112 after the etching operation.

As shown in FIG. 1C, the photoresist layer 110 is removed so that the remaining portion of the metallic layer 102a together with the oxidation-resistant layer 102b form a gate 102.

As shown in FIG. 1D, an insulating layer 104 is formed over the oxidation-resistant layer 102b. Since the sidewalls of the gate 102 have such a poor step profile due to undercutting, the insulating layer 104 can hardly provide the gate 102 with a good coverage so that any subsequently deposited film layers are likely to be affected. In addition, after covering the gate 102 with the insulating layer 104, point discharge may occur through any sharp corner in the oxidation-resistant layer 102b because of an over-etched metallic layer 102a.

### SUMMARY OF THE INVENTION

Accordingly, the present invention is directed to a method of manufacturing a gate, a thin film transistor and a pixel. The method utilizes a ‘lift-off’ technique to fabricate the gate so that poor step coverage and point discharge is no longer a major problem.

According to an embodiment of the present invention, first, a substrate is provided. Thereafter, a patterned mask layer is formed over the substrate. The mask layer exposes an area for forming the gate. A gate is formed within the exposed area. Finally, the mask layer is removed.

The present invention is also directed to a method of manufacturing a thin film transistor based on the aforementioned method of fabricating the gate. After fabricating the gate, an insulating layer is formed over the substrate covering the gate. Thereafter, a channel layer is formed over the insulating layer. Finally, a source and a drain are formed over the channel layer.

In addition, the aforementioned method of manufacturing a thin film transistor can be combined with the process of fabricating a thin film transistor array substrate to form a pixel unit. After forming the source and the drain, a passivation layer is formed over the substrate. The passivation layer has an opening that exposes a portion of the drain. Finally, a pixel electrode is formed over the passivation layer such that the pixel electrode is electrically connected to the drain via the opening.

According to an embodiment of the present invention, the method of forming the gate, the thin film transistor and the pixel unit includes using a lift off technique to form the gate. Hence, compared to the conventional etching process of forming the gate, the method according to an embodiment of the present invention is capable of preventing the formation of undercuts between the metallic layer and the oxidation-resistant layer through over-etching. In other words, the sidewalls of the gate have a good step profile and any subsequently deposited film layers have a good coverage. Ultimately, point discharge from the gate is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the steps of fabricating a conventional gate having an overlying oxidation-resistant layer.

FIGS. 2A through 2D are schematic cross-sectional views showing the steps of fabricating the gate of a thin film transistor according to one embodiment of the present invention.

FIGS. 3A through 3E are schematic cross-sectional views showing the steps of fabricating a pixel unit on a thin film transistor array substrate according to one embodiment of the present invention.

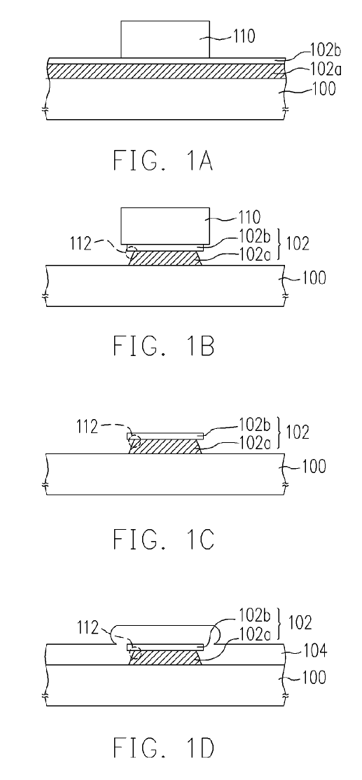

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

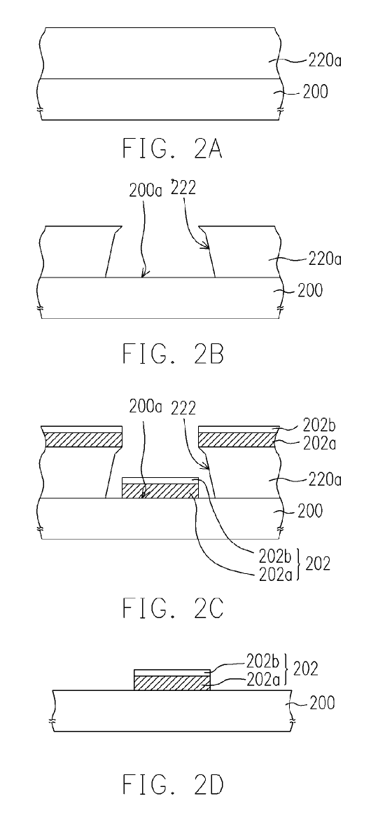

FIGS. 2A through 2D are schematic cross-sectional views showing the steps of fabricating the gate of a thin film transistor according to one embodiment of the present invention. As shown in FIG. 2A, a substrate 200 is provided. Thereafter, a mask material layer 220 is formed over the substrate 200. In one embodiment, the mask material layer 220 is a photoresist layer, for example.

As shown in FIG. 2B, the mask material layer 220 is patterned to form a mask layer 220a having an opening 222 therein. The opening 222 exposes an area 200a for forming a gate. In one embodiment of the present invention, if the mask material layer 220 is fabricated using photoresist material, the method of patterning the mask material layer 220 includes performing an exposure process on the mask material layer 220 using a photomask and then developing the exposed mask material layer 220. In one embodiment of the present invention, the opening 222 in the mask material layer 220 has a top portion wider than its bottom portion.

As shown in FIG. 2C, a gate 202 is formed on the substrate 200 within the area 200a. The gate 202 is formed, for example, by performing a physical vapor deposition process such as sputtering or evaporation. To form the gate 202, a metallic layer 202a is formed over the mask layer 220a and inside the area 200a. Thereafter, an oxidation-resistant layer 202b is formed over the metallic layer 202a. The oxidation-resistant layer 202b mainly serving to prevent the underlying metallic layer 220a from over-oxidation and can be fabricated using a material such as metallic alloy or a metal silicide compound. It should be noted that the metallic layer 202a and the oxidation-resistant layer 202b formed over the mask layer 220a are separated from the metallic layer 202a and the oxidation-resistant layer 202b formed inside the area 200a because there is a height difference between the mask layer 220a and the substrate 200.

As shown in FIG. 2D, the mask layer 220a is removed and the metallic layer 202a and the oxidation-resistant layer 202b on the mask layer 220a is stripped at the same time. The remaining metallic layer 202a and the oxidation-resistant layer 202b inside the area 200a together form a gate 202.

According to an embodiment of the present invention, a lift-off method is utilized instead of the conventional wet etching method to form the gate of a thin film transistor so that the sidewalls of the gate could have a good step profile. The aforementioned photoresist layer serves as a deposition mask. The photoresist layer can be formed by, for example, spin coating liquid photoresist or electro-depositing photoresist. Within a reasonable range, other organic material (or even inorganic material) can be used to form the mask layer. Furthermore, other methods of forming the mask layer may be used such as jet coating.

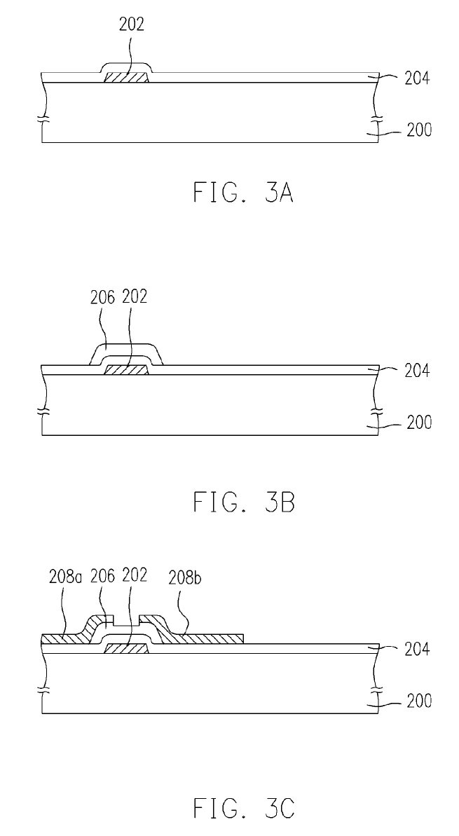

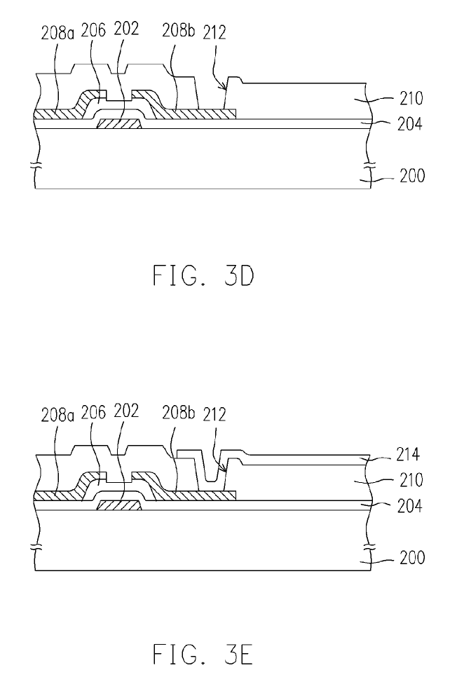

The present invention is also directed to a method of fabricating a thin film transistor and pixel unit by incorporating the aforementioned method of forming the gate. FIGS. 3A through 3C are schematic cross-sectional views showing the steps of forming a thin film transistor according to an embodiment of the present invention. FIGS. 3A through 3E are schematic cross-sectional views showing the steps of fabricating a pixel unit on a thin film transistor array substrate according to one embodiment of the present invention. As shown in FIG. 3A, a substrate 200 having the aforementioned gate 202 thereon is provided. Next, insulating material is globally deposited over the substrate 200 to form an insulating layer 204 that covers the gate 202.

As shown in FIG. 3B, a semiconductor material layer (not shown) is formed over the insulating layer 204. The semiconductor material layer is patterned by performing the well known process including photolithography and etching process to form a channel layer 206. The channel layer 206 is positioned on the insulating layer 204 above the gate 202. The channel layer 206 is fabricated using amorphous silicon (a-Si), for example. In addition, an ohmic contact layer (not shown), for example, made from a doped amorphous silicon material, may also be formed on the surface of the channel layer 206.

As shown in FIG. 3C, another metallic layer (not shown) is formed over the substrate 200. The metallic layer is patterned by performing the well known photolithography and etching process to form a source/drain 208a/208b over the channel layer 206. In this step further includes a step of partially removing a portion of the channel layer 206 using the source/drain 208a/208b as an etching mask.

After forming the thin film transistor, subsequent steps are carried out for forming the pixel unit. As shown in FIG. 3D, a passivation layer 210 is formed over the substrate 200 to cover the source/drain 208a/208b. Thereafter, the passivation layer 210 is patterned by performing the well known photolithography and etching process to form an opening 21 2 that exposes the drain 208b.

As shown in FIG. 3E, an indium-tin-oxide electrode layer (not shown) is formed over the passivation layer 210 and in the opening 212. The indium-tin-oxide layer is similarly patterned by performing the well known photolithography and etching process to form a pixel electrode 214. The pixel electrode 214 is electrically connected to the drain 208a via the opening 212.

In summary, the method of forming the gate, thin film transistor and pixel unit according to an embodiment of the present invention includes a lift off technique to form the gate. Using the lift off technique, the formation of undercuts between the metallic layer and the oxidation-resistant layer through over-etching is prevented so that the sidewalls of the gate can have a good step profile. Hence, in any subsequent step of fabricating the thin film transistor or the pixel unit, all the deposited film layers have a good coverage. Ultimately, point discharge from the gate is effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a gate, comprising the steps of:
providing a substrate;
forming a patterned mask layer over the substrate, wherein the patterned mask layer exposes an area on the substrate for forming the gate;
forming a gate on the substrate within the exposed area; and
removing the mask layer.

2. The method of claim 1, wherein the step of forming the gate further comprises a step of forming a metallic layer over the mask layer and inside the exposed area such that the metallic layer formed over the mask layer is apart from the metallic layer formed inside the exposed area.

3. The method of claim 2, further comprising a step of forming an oxidation-resistant layer over the metallic layer after the step of forming the metallic layer.

4. The method of claim 3, wherein the oxidation-resistant layer is selected from a group consisting of an alloy of metals and a metal silicide compound.

5. The method of claim 1, wherein the step of forming the gate comprises performing a physical vapor deposition process.

6. The method of claim 1, wherein the mask layer comprises a photoresist layer.

7. A method of fabricating a pixel unit, comprising the steps of:
providing a substrate;
forming a patterned mask layer over the substrate, wherein the patterned mask layer exposes an area on the substrate for forming the gate;
forming a gate on the substrate within the exposed area;
removing the mask layer;
forming an insulating layer over the substrate to cover the gate;
forming a channel layer over the insulating layer above the gate;
forming a source and a drain over the channel layer;
forming a passivation layer over the substrate, wherein the passivation layer has an opening that exposes a portion of the drain; and
forming a pixel electrode over the passivation layer such that the pixel electrode is electrically connected to the drain via the opening.

8. The method of claim 7, wherein the step of forming the gate further comprises forming a metallic layer over the mask layer and inside the exposed area such that the metallic layer formed over the mask layer is apart from the metallic layer formed within the exposed area.

9. The method of claim 8, further comprising a step of forming an oxidation-resistant layer over the metallic layer after the step of forming the metallic layer.

10. The method of claim 9, wherein the oxidation-resistant layer is selected from a group consisting of an alloy of metals and a metal silicide compound.

11. The method of claim 7, wherein the step of forming the gate comprises performing a physical vapor deposition process.

12. The method of claim 7, wherein the mask layer comprises a photoresist layer.

13. A method of fabricating a thin film transistor, comprising the steps of:
providing a substrate;
forming a patterned mask layer over the substrate, wherein the mask layer exposes an area on the substrate for forming the gate;
forming a gate within the exposed area;
removing the mask layer;
forming an insulating layer over the substrate to cover the gate;
forming a channel layer over the insulating layer above the gate; and
forming a source and a drain over the channel layer.

14. The method of claim 1 3, wherein the step of forming the gate further comprises forming a metallic layer over the mask layer and inside the exposed area such that the metallic layer formed over the mask layer is apart from the metallic layer formed within the exposed area.

15. The method of claim 14, further comprising a step of forming an oxidation-resistant layer over the metallic layer after the step of forming the metallic layer.

16. The method of claim 1 5, wherein the oxidation-resistant layer is selected from a group consisting of an alloy of metals and a metal silicide compound.

17. The method of claim 13, wherein the step of forming the gate comprises performing a physical vapor deposition process.

18. The method of claim 13, wherein the mask layer comprises a photoresist layer.
